(19) United States
(12) Patent Application Publication
(10) Pub. No.: US 2003/0057510 A1
(43) Pub. Date: Mar. 27, 2003

(54) Capacitance element and boosting circuit using the same

(76) Inventor: Motoharu Ishii, Tokyo (JP)

Correspondence Address: Platon N. Mandros, BURNS, DOANE, SWECKER & MATHIS, L.L.P., P.O. Box 1404, Alexandria, VA, 22313-1404, US

(21) Appl. No.: 10/216,180

(22) Filed: Aug. 12, 2002

(30) Foreign Application Priority Data
Sep. 27, 2001 (JP) 2001-297623

(51) Int. Cl. H01L 29/76

(52) U.S. Cl. 257/452

(57) ABSTRACT

A gate insulation film is provided on the surface of silicon substrate, a first gate electrode is provided on the gate insulation film, an interlayer insulation film is provided on the first gate electrode, a second gate electrode is provided on the interlayer insulation film, and the first gate electrode is fixed at a reference potential. Subsequently, a predetermined voltage is applied to the part of the substrate opposed to the first and second gate electrodes.

### BACKGROUND OF THE INVENTION

1. Field of the Invention

The present invention relates to a capacitance element used in semiconductor integrated circuits and to a boosting circuit using the element.

2. Description of the Prior Art

As an example of capacitance elements used in semiconductor integrated circuits, there are a junction capacitance between the area of the source/drain and the silicon substrate of MOS transistors, a gate capacitance between the gate electrode and the silicon substrate of MOS transistors, and so on. In general, a gate capacitance is used as a decoupling capacitor used for measures against noise in semiconductor integrated circuits or as a capacitance element used for boosting circuits because of its easiness of production.

FIG. 7 is a sectional view showing the schematic configuration of a gate capacitance that is a conventional capacitance element used in semiconductor integrated circuits. Referring to FIG. 7, a pair of N⁺ type source/drain areas 102, 103 are formed in the vicinity of the surface of P type silicon substrate 101, gate electrode 104 is formed on a gate insulation film formed between the pair of source/drain areas 102, 103 on the surface of silicon substrate 101, and ground 105 is connected to silicon substrate 101 and source/drain area 103. Gate capacitance 106 exists between gate electrode 104 and silicon substrate 101. In FIG. 7, the gate insulation film is omitted and not shown.

The operation will next be described.

Silicon substrate 101 is connected to ground 105, and is fixed at a reference potential. A predetermined voltage V is applied to gate electrode 104 as shown in FIG. 8. As a result, electric charge is stored in gate capacitance 106 existing between gate electrode 104 and silicon substrate 101.

Because the gate capacitance that is a conventional capacitance element used in semiconductor integrated circuits is arranged as mentioned above, the gate insulation film cannot be made thin on the grounds of ensuring reliability. For this reason, the area of the capacitance element cannot be reduced in order to secure a necessary capacitance value. As a result, there has been a drawback that the miniaturization of semiconductor integrated circuits is hindered.

### SUMMARY OF THE INVENTION

The present invention has been accomplished to solve the above-mentioned drawback. An object of the present invention is to provide a capacitance element having a large capacitance value per the unit area and being used in semiconductor integrated circuits and to provide a boosting circuit using the element.

According to a first aspect of the present invention, there is provided a capacitance element including: a gate insulation film provided on the surface of the substrate; a first gate electrode provided on the gate insulation film; an interlayer insulation film provided on the first gate electrode; and a second gate electrode provided on the interlayer insulation film, wherein the first gate electrode is connected to the ground and thereby is fixed at a reference potential.

According to a second aspect of the present invention, there is provided a boosting circuit including: a group of diodes including a plurality of diodes connected in series; a first capacitance element to which a first clock signal is input; and a second capacitance element to which a second clock signal that is complementary to the first clock signal is input, wherein the first capacitance element and the second capacitance element are alternately connected to the terminals of the group of diodes connected in series,

the first and second capacitance elements each including: a gate insulation film provided on the surface of the substrate; a first gate electrode provided on the gate insulation film; an interlayer insulation film provided on the first gate electrode; and a second gate electrode provided on the interlayer insulation film,

wherein the first gate electrode is connected to the ground and thereby is fixed at a reference potential.

### BRIEF DESCRIPTION OF THE DRAWINGS

FIG. 1 is a sectional view showing the configuration of the capacitance element according to an embodiment 1 of the present invention;

FIG. 2 is a figure used for describing the operation of the capacitance element according to the embodiment 1 of the present invention;

FIG. 3 is a sectional view showing the schematic configuration of the memory cell of a flash memory;

FIG. 4 is a sectional view showing the configuration of the capacitance element produced in the manufacturing process of the memory cell of the flash memory shown in FIG. 3, according to an embodiment 2 of the present invention;

FIG. 5 is a figure used for describing the operation of the capacitance element according to the embodiment 2 of the present invention;

FIG. 6 is a circuit diagram showing the configuration of a boosting circuit;

FIG. 7 is a sectional view showing the schematic configuration of a gate capacitance that is a conventional capacitance element; and

FIG. 8 is a figure used for describing the operation of a gate capacitance that is a conventional capacitance element.

### DETAILED DESCRIPTION OF THE PREFERRED EMBODIMENTS

An embodiment of the present invention will be described below.

Embodiment 1

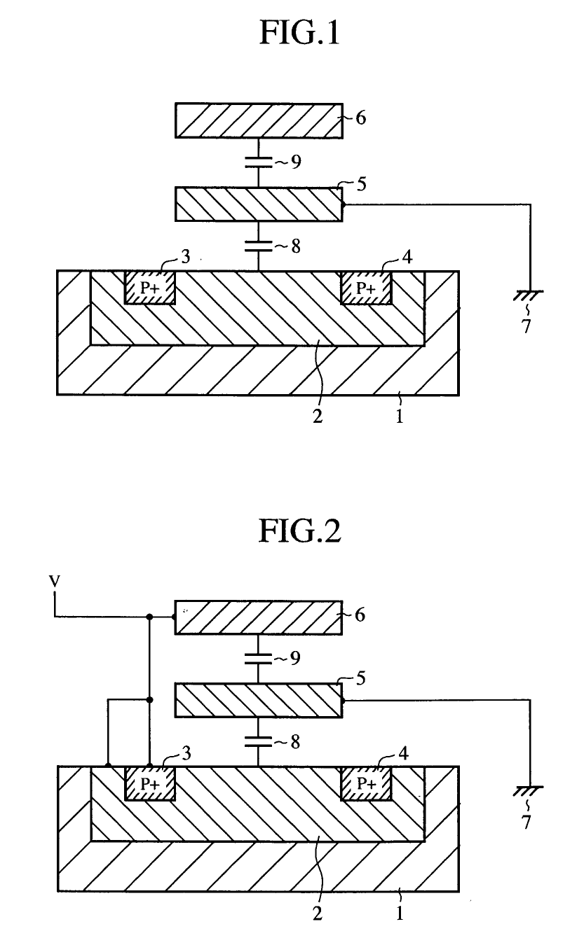

FIG. 1 is a sectional view showing the configuration of the capacitance element used in semiconductor integrated circuits, according to an embodiment 1 of the present invention. Referring to FIG. 1, N well 2 is formed within P type silicon substrate 1, a pair of P⁺ type source/drain areas 3, 4 are formed in the vicinity of the surface of the area of substrate 1 where N well 2 is formed, first gate electrode 5 is provided on a gate insulation film formed at the position between a pair of source/drain areas 3 and 4 on the surface of silicon substrate 1 where N well 2 is located, second gate electrode 6 is provided on an interlayer insulation film formed on first gate electrode 5, and ground 7 is connected to first gate electrode 5. First capacitance 8 exists between first gate electrode 5 and silicon substrate 1, and second capacitance 9 exists between second gate electrode 6 and first gate electrode 5. By the way, the gate insulation film and the interlayer insulation film are omitted and not shown in FIG. 1.

The operation will next be described.

First gate electrode 5 is connected to ground 7, and fixed at the reference potential. As shown in FIG. 2, a predetermined voltage V is applied to N well 2 and source/drain area 3, to thereby apply the predetermined voltage V to the part of silicon substrate 1 opposed to first gate electrode 5, and simultaneously the predetermined voltage V is applied to second gate electrode 6. As a result, electrical charge is stored at first capacitance 8 existing between first gate electrode 5 and silicon substrate 1, and at second capacitance 9 existing between second gate electrode 6 and first gate electrode 5.

As mentioned above, according to the embodiment 1, the gate insulation film, first gate electrode 5, interlayer insulation film, and second gate electrode 6 are successively provided on the surface of silicon substrate 1, and first gate electrode 5 is fixed at a reference potential. Subsequently, a predetermined voltage V is applied to the part of silicon substrate 1 opposed to first gate electrode 5 and second gate electrode 6. Thereby, electrical charge can be stored in first capacitance 8 existing between first gate electrode 5 and silicon substrate 1, and in second capacitance 9 existing between second gate electrode 6 and first gate electrode 5, thereby increasing a capacitance value per the unit area of the capacitance element. For instance, when the area of first gate electrode 5 is equal to the area of second gate electrode 6 and the film thickness of the gate insulation film is equal to the film thickness of the interlayer insulation film, the capacitance value per the unit area is twice as high as the value in the conventional case.

Here, in the embodiment 1, a capacitance element having a configuration in which N well 2 is formed within silicon substrate 1, subsequently a gate insulation film, first gate electrode 5, an interlayer insulation film, and second gate electrode 6 are successively formed on the surface of silicon substrate 1 where N well 2 is located, and then first gate electrode 5 is fixed at a reference potential was described. However, the same advantageous effect can be obtained when a capacitance element was arranged such that a P well is formed within a silicon substrate, subsequently a gate insulation film, a first gate electrode, an interlayer insulation film, and a second gate electrode are successively formed on the surface of the silicon substrate where the P well is located, and then the first gate electrode is fixed at a reference potential.

Embodiment 2

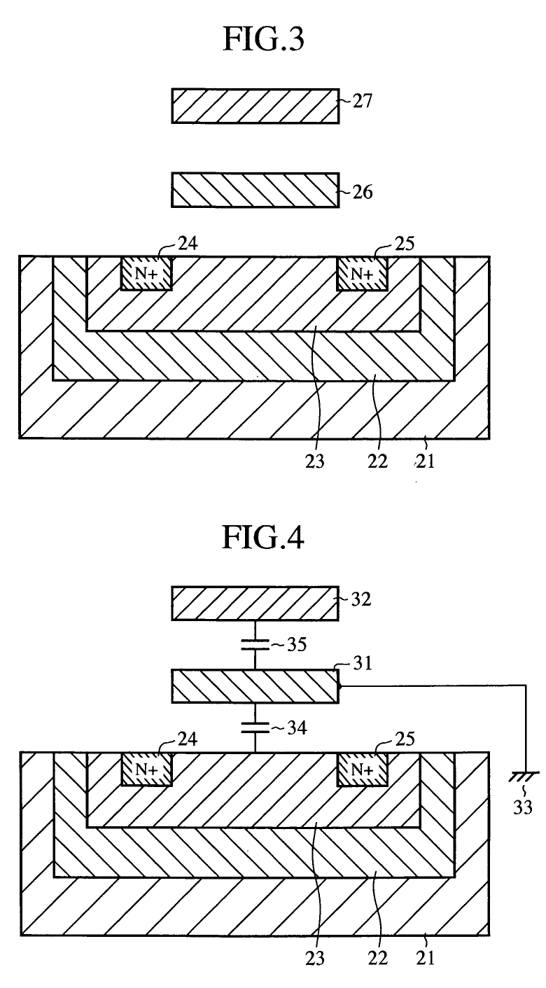

FIG. 3 is a sectional view showing the schematic configuration of the memory cell of a flash memory. Referring to FIG. 3, bottom N well 22 is formed within P type silicon substrate 21, P well 23 is formed within bottom N well 22, a pair of N⁺ type source/drain areas 24, 25 are formed in the vicinity of the surface of the area of silicon substrate 21 where P well 23 is formed, floating gate 26 is provided on a gate insulation film formed at the position between a pair of source/drain areas 24 and 25 on the surface of silicon substrate 21 where P well 23 is located, and control gate 27 is provided on an interlayer insulation covering floating gate 26. However, the gate insulation film and the interlayer insulation film are omitted and not shown in FIG. 3.

As shown in FIG. 3, the memory cell of the flash memory is arranged such that the gate insulation film, floating gate 26, the interlayer insulation film, and control gate 27 are successively formed on the surface of silicon substrate 21. Thereby, when floating gate 26 was connected to the ground, and fixed at a reference potential, electrical charge can be stored between floating gate 26 and silicon substrate 21 and also between control gate 27 and floating gate 26 by applying a voltage V to the part of silicon substrate 21 opposed to floating gate 26 and control gate 27. Accordingly, a capacitance element can be produced in the process where the memory cell of a flash memory is manufactured.

FIG. 4 is a sectional view showing the configuration of the capacitance element used in semiconductor integrated circuits, produced in the manufacturing process of the memory cell of the flash memory shown in FIG. 3, according to Embodiment 2 of the present invention. Referring to FIG. 4, first gate electrode 31 is provided on a gate insulation film formed at the position between a pair of source/drain areas 24, 25 on the surface of silicon substrate 21 where P well 23 is located, second gate electrode 32 is provided on an interlayer insulation film covering first gate electrode 31, and ground 33 is connected to first gate electrode 31. First capacitance 34 exists between first gate electrode 31 and silicon substrate 21, and second capacitance 35 exists between second gate electrode 32 and first gate electrode 31. However, the gate insulation film and the interlayer insulation film are omitted, and not shown in FIG. 4.

The operation will next be described.

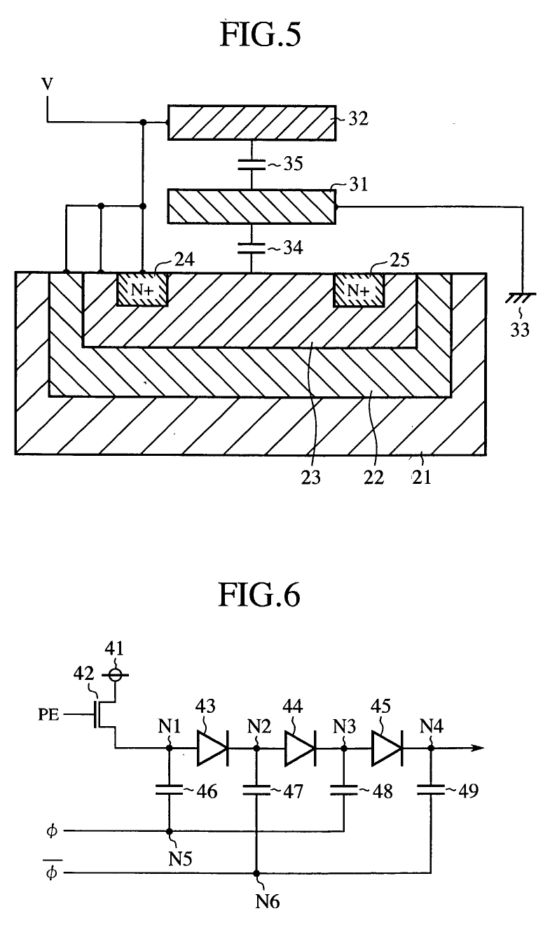

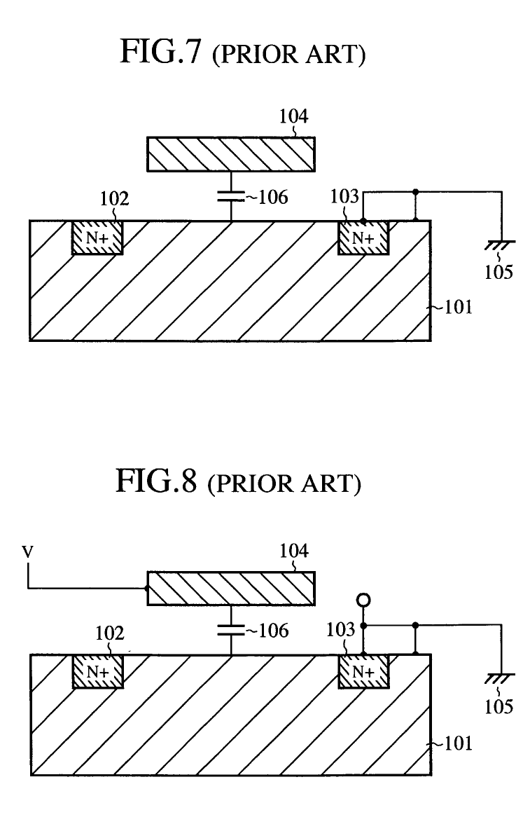

First gate electrode 31 is connected to ground 33, and fixed at a reference potential. As shown in FIG. 5, a predetermined voltage V is applied to bottom N well 22, P well 23, and source/drain area 24, to thereby apply the predetermined voltage V to the part of silicon substrate 21 opposed to first gate electrode 31, and simultaneously the predetermined voltage V is applied to second gate electrode 32. As a result, electrical charge is stored at first capacitance 34 existing between first gate electrode 31 and silicon substrate 21, and at second capacitance 35 existing between second gate electrode 32 and first gate electrode 31.

As mentioned above, according to the embodiment 2, the gate insulation film, first gate electrode 31, the interlayer insulation film, and second gate electrode 32 are successively formed on the surface of silicon substrate 21, and first gate electrode 31 is fixed at a reference potential. Subsequently, a predetermined voltage V is applied to the part of silicon substrate 21 opposed to first gate electrode 31 and second gate electrode 32. Thereby, the similar advantageous effect to that of the embodiment 1 is obtained.

Embodiment 3

FIG. 6 is a circuit diagram showing the configuration of a boosting circuit. Referring to FIG. 6, NMOS transistor 42 was connected with power supply 41 and first node N1, first diode 43 was connected with first node N1 and second node N2, second diode 44 was connected with second node N2 and third node N3, third diode 45 was connected with third node N3 and fourth node N4, first capacitance element 46 was connected with fifth node N5 to which pulsed clock signal Φ is given and with first node N1, second capacitance element 47 was connected with sixth node N6 to which pulsed clock signal/Φ that is complementary to clock signal Φ is given and with second node N2, third capacitance element 48 was connected with fifth node N5 and third node N3, and fourth capacitance element 49 was connected with sixth node N6 and fourth node N4. First to third diodes 43-45 are connected in series, to thereby constitute a group of diodes. A capacitance element to which clock signal Φ is input and a capacitance element to which clock signal/Φ is input are alternately connected with the group of diodes with the diode in between.

The capacitance elements described in the embodiment 1 or embodiment 2 are used as first to fourth capacitance elements 46-49.

The operation will next be described.

An enable signal at H level PE is input to the gate of NMOS transistor 42, and NMOS transistor 42 enters an on-state. At that time, when clock signal Φ is input to first capacitance element 46 and third capacitance element 48 and clock signal/Φ is input to second capacitance element 47 and fourth capacitance element 49, the potential of first to fourth nodes N1-N4 moves up or down synchronizing with clock signal Φ and clock signal/Φ. For instance, when the potential of first node N1 and third node N3 rose, the potential of second node N2 and fourth node N4 is about to fall, but the potential of second node N2 and fourth node N4 does not greatly fall because of the characteristic of the diodes. At the next time, when the potential of second node N2 and fourth node N4 rose, the potential of first node N1 and third node N3 is about to fall, but the potential of first node N1 and third node N3 does not greatly fall because of the characteristic of the diodes. Such repetition makes the potential of fourth node N4 sufficiently higher than the potential of power supply 41.

As mentioned above, according to the embodiment 3, because the capacitance element described in the embodiment 1 or embodiment 2 is used as a capacitance element constituting a boosting circuit, the effect that the area of a boosting circuit can be reduced is obtained.

Incidentally, the capacitance elements described in the embodiment 1 and embodiment 2 can be used not only for a boosting circuit, but also for a decoupling capacitance used for measures against noise in semiconductor integrated circuits, for instance.

What is claimed is:

1. A capacitance element comprising:
a gate insulation film provided on the surface of a substrate;
a first gate electrode provided on the gate insulation film;
an interlayer insulation film provided on the first gate electrode; and
a second gate electrode provided on the interlayer insulation film, wherein the first gate electrode is connected to the ground and thereby is fixed at a reference potential.

2. The capacitance element according to claim 1, wherein a well region and source/drain regions are formed in the substrate located under the first and second gate electrodes, wherein a predetermined voltage is applied to said second gate electrode and well region, and at least one of said source/drain regions.

3. The capacitance element according to claim 2, wherein a bottom well is formed to surround the well region and source/drain regions, and the predetermined voltage is also applied to said bottom well.

4. A boosting circuit comprising:
a group of diodes including a plurality of diodes connected in series;
a first capacitance element to which a first clock signal is input; and
a second capacitance element to which a second clock signal that is complementary to the first clock signal is input, wherein the first capacitance element and the second capacitance element are alternately connected to the terminals of the group of diodes connected in series,
said first and second capacitance elements each including:
a gate insulation film provided on the surface of the substrate;
a first gate electrode provided on the gate insulation film;
an interlayer insulation film provided on the first gate electrode; and
a second gate electrode provided on the interlayer insulation film,
wherein the first gate electrode is connected to the ground and thereby is fixed at a reference potential.
